(19) United States
(12) Patent Application Publication
(10) Pub. No.: US 2013/0042905 A1
(43) Pub. Date: Feb. 21, 2013

(54) DEVICE, PANEL HOLDER AND SYSTEM FOR GENERATING ELECTRICITY FROM SOLAR RADIATION

(71) Applicant: Petrus Paulus Carolus Maria Stassen, Waalwijk (NL)

(72) Inventor: Petrus Paulus Carolus Maria Stassen, Waalwijk (NL)

(73) Assignee: TULIPPS SOLAR INTERNATIONAL B.V., Eindhoven (NL)

(21) Appl. No.: 13/576,078

(22) PCT Filed: Feb. 4, 2011
(86) PCT No.: PCT/NL2011/050081

§ 371 Date: Oct. 24, 2012

(30) Foreign Application Priority Data
Feb. 5, 2010 (NL) 2004206

(51) Int. Cl. H01L 31/048

(52) U.S. Cl. 136/251

(57) ABSTRACT

A device (1) for generating electrical energy from solar radiation includes a panel holder (3) with a wall for supporting therewith on a surface and a solar panel (2) which supports on an upright edge of the panel holder extending from the wall. The wall, the solar panel and the upright edge bound a cavity space (7) in which at least one strengthening element (11) is provided which extends from the wall to a rear side of the solar panel facing toward the cavity space for additional support of the solar panel. An extremely stiff and strong device is thus provided which makes it possible with a thin solar panel to comply with the strength requirements for such devices.

### CROSS-REFERENCE TO RELATED APPLICATIONS

This application is the National Stage of International Application No. PCT/NL2011/050081, filed Feb. 4, 2011, which claims the benefit of Netherlands Application No. 2004206, filed Feb. 5, 2010, the contents of which is incorporated by reference herein.

### FIELD OF THE INVENTION

The present invention relates to a device for generating electrical energy from solar radiation, comprising a panel holder with a bottom wall for supporting therewith on a surface and a solar panel which supports on a side wall of the panel holder extending from the bottom wall. The present invention also relates to a panel holder as applied in the device.

### BACKGROUND OF THE INVENTION

A known device of the type stated in the preamble is based on a panel holder comprising a bottom wall with side wall which holds a photovoltaic solar panel at a peripheral edge. Besides supporting the solar panel, the panel holder also serves to protect the solar panel during transport and installation of the device. For further protection of the solar panel in the unlikely event of breakage after installation of the device, for instance as a result of impact of objects such as for instance hailstones, a relatively thick glass panel is applied as solar panel. Although this results in a device which is very well able per se to generate electrical energy from the solar radiation incident on the photovoltaic solar panel, this known device does however also have a drawback. Through use of the relatively thick sheet of glass the known device has a high overall weight such that it precludes application on a surface which allows only a low weight loading, such as for instance light industrial roofs.

### SUMMARY OF THE INVENTION

The present invention thus has for its object, among others, to provide a device which obviates said drawback.

In order to achieve the stated object a device of the type stated in the preamble has the feature according to the invention that the bottom wall, the solar panel and the side wall bound a cavity space in which at least one strengthening element extends from the bottom wall to a rear side of the solar panel in order to further support the solar panel which comprises a glass panel with a thickness of a maximum of 4 millimetres, in particular a thickness of 2 millimetres or less. Owing to the at least one strengthening element the solar panel is supported not only by the side wall close to a peripheral edge thereof, but also at at least one more central additional location. This results in an extremely stiff and strong device which makes it possible with a relatively thin glass panel to comply with the strength requirements for such devices, as described in the IEC 61215 and IEC 61646 standards. In the case of for instance a glass panel with dimensions of 160 cm by 100 cm and a thickness of 2 mm the panel holder thus provides a sufficiently stiff and strong device which conforms to the IEC 61215 and IEC 61646 standards. By making use of a relatively thin glass panel an overall weight of the device is considerably lower compared to known devices on which glass panels of 4 mm or thicker are applied. The device according to the invention is hereby more widely applicable, for instance on relatively light, industrial or other roofs. The device according to the present invention makes this possible with the strengthening elements.

In addition to a reduction in the overall weight of the device, a relatively thin glass panel also result in a cost-saving. Less material is needed for the relatively thin panel and the production costs are moreover considerably lower since a curing oven necessary for the production of the glass panel has a higher capacity in the case of a thinner panel. A light transmission of a glass panel moreover depends on the thickness thereof. The light transmission of a glass panel of 2 mm thickness is thus considerably higher than a light transmission of conventional glass panels of 4 mm thickness. In the case of a glass panel with a maximum thickness of 2 mm the light transmission is even sufficient to enable so-called float glass to be applied instead of the usual, much more expensive solar glass. The present invention is hereby also highly suitable for a solar panel which, in addition to the relatively thin glass panel, comprises at least a further relatively thin glass panel, for instance in order to receive the photovoltaic cells of the solar panel in protected position between the glass panel and the further glass panel. For the solar panel use can thus for instance be made of a 1-4 mm thick glass panel as protective plate of the device, against which a 1-4 mm thick further glass panel is arranged on a rear side as support plate for a film of photovoltaic cells clamped between the panels. Both glass panels can thus take a relatively thin form, which makes a weight reduction possible as well as resulting in advantages during production. A light transmission through the protective plate is moreover sufficient here to enable the glass panel to be produced from float glass. A specific thickness of the two panels can be geared to each other as desired and for instance be adapted to a permissible overall weight of the device for a specific application. For an application on relatively light roofs use can thus be made of a solar panel with a glass panel with a maximum thickness of 2 mm, whereby the overall weight of the device is very low, while a solar panel having two glass panels with a maximum thickness of 4 mm can be applied on heavier roofs. The overall weight of the device is hereby comparatively higher, but both glass panels are relatively thin and can thus be produced with great production advantages and higher transmission values.

A further preferred embodiment of the device according to the present invention has the feature that the at least one strengthening element comprises a strengthening rib. In addition to imparting an optimal stiffness, a rib construction also imparts an excellent bending strength to the device. Very thin glass panels can hereby be supported reliably by the panel holder.

A further preferred embodiment of the device according to the present invention has the feature that the at least one strengthening rib divides the cavity space between the bottom wall and the solar panel into a first channel and at least one further channel at least substantially separated therefrom, and that each channel comprises an inlet and an outlet. By allowing a heat-carrying medium such as air or water to flow through the channels between the inlet and outlet, the device provides for a thermal regulation of the solar panel, this resulting in an increased efficiency of the solar panel. An alternative embodiment of the device according to the present invention has the feature that the panel holder comprises a set of strengthening ribs which extend from the bottom wall to the solar panel and around which a flow channel meanders between an inlet and an outlet.

A further preferred embodiment of the device according to the present invention has the feature that inside the cavity space the panel holder comprises at least a primary strengthening rib extending in a longitudinal direction and comprises at least a secondary strengthening rib extending in a width direction at least substantially transversely of the longitudinal direction. A bending stiffness and strength of the device is thus increased in both the longitudinal direction and width direction.

A further preferred embodiment of the device according to the present invention has the feature that the secondary strengthening rib is connected at a first outer end to a first primary strengthening rib and is connected at an opposite, second outer end to the side wall or a subsequent further primary strengthening rib. The panel holder thus comprises mutually connected primary and secondary strengthening ribs which make the panel holder extremely strong and stiff, particularly when use is made for the panel holder of fibre-reinforced plastic so that a very thin glass panel with thicknesses of at least practically 2 mm or thinner can be reliably placed thereon.

In a particular embodiment hereof the device according to the present invention has the feature that the secondary strengthening rib leaves a channel opening between the bottom wall and the solar panel. The secondary strengthening rib thus does not form a full closure of a channel which is provided between the primary strengthening ribs and through which a heat-carrying medium can flow in order to provide for a thermal regulation of the solar panel, while the overall stiffness of the panel holder is not diminished, or hardly so.

In a further preferred embodiment the device according to the present invention has the feature that the at least one strengthening rib comprises a heat-conducting material. The at least one strengthening rib hereby forms a good thermal conductor which enhances a thermal regulation of the solar panel by discharging heat from the solar panel to a heat-carrying medium in the cavity space.

For a practical mounting of the solar panel on the panel holder, the device according to the present invention is characterized in a preferred embodiment in that the solar panel is adhered to the side wall using an adhesive. In a particular embodiment the device according to the present invention is however characterized in that the side wall comprises a groove in which the solar panel can be guided with a peripheral edge part. The guiding provides for an extremely simple and rapid mounting of the solar panel on the panel holder, wherein a correct positioning of the solar panel on the panel holder is ensured, with a space present therebetween being fully enclosed. In a further particular embodiment the device according to the present invention is characterized in that the peripheral edge part fixes clampingly in the groove. The clamping fixation makes additional fixation means, for instance mechanical mounting means such as bolts and chemical adhesives such as glue, unnecessary and moreover avoids the solar panel being affected by such fixation means.

For a simple placing of the device on a surface suitable for the purpose, the device according to the present invention is characterized in a further preferred embodiment in that the panel holder is provided with at least one support element for supporting on the surface therewith. For a reliable mounting on the surface the device according to the present invention is characterized in that the at least one support element is provided with fixation means for fixation of the panel holder to the surface. The device is thus prevented from displacing, rotating or tilting after being placed on the surface.

In a further preferred embodiment the device according to the present invention is characterized in that the at least one support element comprises a support surface on which the panel holder supports and comprises a further support surface which is able and adapted to simultaneously receive at least one further panel holder thereon. Because such a support element can support a plurality of panel holders at a time, fewer support elements are needed per panel holder. This therefore results in a considerable further weight-saving.

In a further preferred embodiment the device according to the present invention is characterized in that the support surface is situated at a first height relative to the surface in order to impart at least substantially the first height relative to the surface to a panel holder received thereon, and that the further support surface is situated at a second height, differing from the first height, relative to the surface in order to impart at least substantially the second height relative to the surface to a further panel holder received thereon. By allowing a panel holder to support with one side on the support surface of the support element and allowing it to support with an opposite side on the further support surface of a further support element an angle will be imparted to the panel holder which enables an efficient capture of solar radiation.

In a further preferred embodiment the device according to the present invention is characterized in that the panel holder comprises a plastic, particularly a plastic chosen from the group of PP, PE, PVC, PA, PET, fibre-reinforced variants thereof, such as glass fibre variants, a combination of two or more thereof, or a thermosetting synthetic resin such as fibre-reinforced polyester as sheet moulding compound or as bulk moulding compound. The use of plastic provides an excellent bearing strength in relation to an overall weight thereof and is moreover durable, weather-resistant and maintenance-friendly.

In a further preferred embodiment the device according to the present invention is characterized in that the panel holder and the at least one support element form an integral whole. The panel holder and the support element can be produced in the factory so that, for placing of the device according to the present invention, the panel holder can be placed in simple manner on a surface suitable for the purpose and the solar panel can then be mounted thereon. Another option is for the panel holder and the solar panel to be produced in the factory as a relatively flat box-like body, which can as a result be stored and transported effectively. For the purpose of placing of the device according to the present invention this box-like body is mounted in simple manner on support elements already provided for this purpose on the surface. The mounting is for instance possible by glueing or for instance by making use of snap bodies.

In a further preferred embodiment the device according to the present invention is characterized in that the panel holder comprises coupling means for a coupling to a further panel holder of a further device. A plurality of devices can thus be mutually coupled, wherein the solar panels form an at least substantially wholly closed active surface between which substantially no inactive parts occur. The invention therefore further relates to a system for generating electrical energy from solar radiation, comprising a set of mutually coupled devices according to the present invention.

### BRIEF DESCRIPTION OF THE DRAWINGS

The invention will now be further elucidated on the basis of a number of exemplary embodiments and associated drawings. In the drawings:

FIG. 1 is a perspective view of a first exemplary embodiment of a device according to the invention with an enlargement of a corner part,

FIG. 2 is a view of a cross-section along line A of FIG. 1 of the first exemplary embodiment of a device according to the invention,

FIG. 3 is a perspective view of a second exemplary embodiment of a device according to the invention,

FIGS. 4 A,B show a corner part of a first exemplary embodiment of a panel holder according to the invention in respectively a top view and a perspective view,

FIGS. 5 A,B show a second exemplary embodiment of a panel holder according to the invention in respectively a top view and a perspective view of a corner part,

FIGS. 6 A,B show a third exemplary embodiment of a panel holder according to the invention in respectively a top view and a perspective view of a corner part,

FIG. 7 is a perspective view of a first exemplary embodiment of a system according to the invention, and

FIG. 8 is a perspective view of a second exemplary embodiment of a system according to the invention.

### DETAILED DESCRIPTION OF THE INVENTION

The figures are otherwise purely schematic and not drawn to scale. For the sake of clarity some dimensions in particular may be exaggerated to greater or lesser extent. Corresponding parts are designated as far as possible in the figures with the same reference numeral.

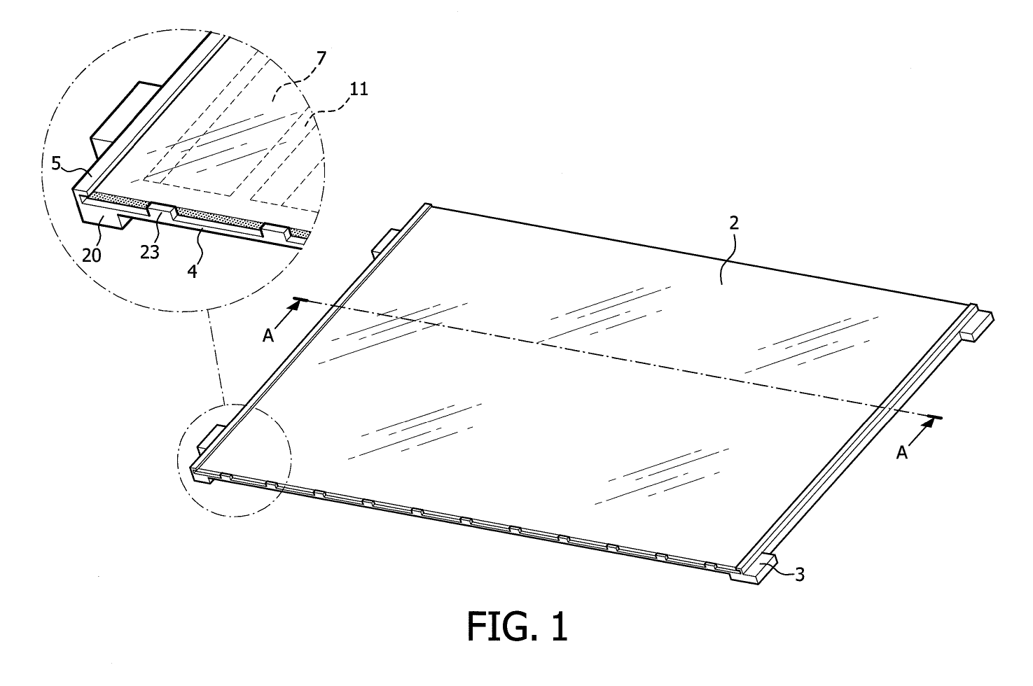

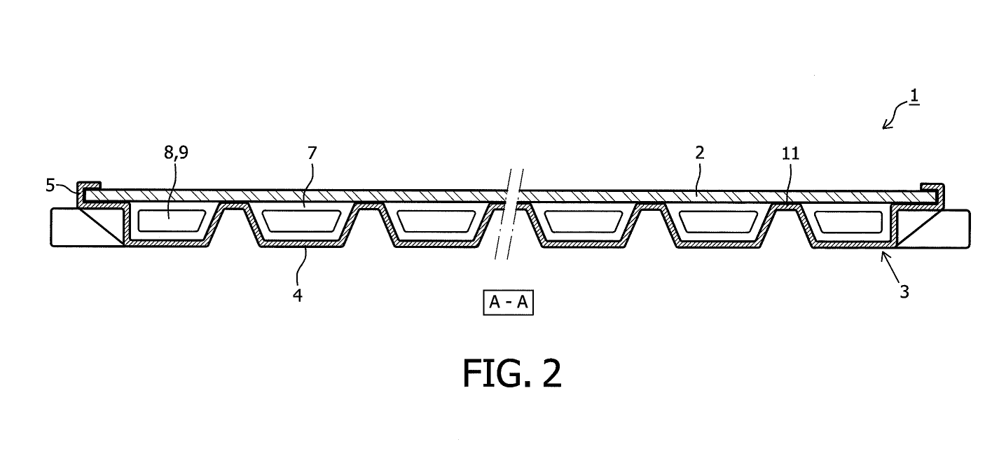

As shown in FIGS. 1 and 2 in a first exemplary embodiment of a device according to the invention, device 1 comprises a solar panel 2 which is mounted on a panel holder 3. Panel holder 3 comprises an at least substantially flat bottom wall 4 provided on an underside with support elements 20 for supporting therewith on a surface. Bottom wall 4 comprises on either side a side wall 5 on which solar panels 2 supports. Side wall 5 is provided for this purpose with a groove in which a peripheral edge part of solar panel 2 is clampingly fixed. Owing to the clamping fixation additional fixation means are unnecessary, so avoiding that solar panel 2 is affected by such fixation means. By guiding solar panel 2 with peripheral edge part through the groove, the groove moreover provides for a simple placing of solar panel 2 on panel holder 3. In a correct position of solar panel 2 on panel holder 3 an outer end of solar panel 2 abuts against stop profiles 23 intended for this purpose and provided on the panel holder on a longitudinal side extending between side walls 5. Situated between bottom wall 4, solar panel 2 and side walls 5 is a cavity space 7 in which a number of strengthening ribs 11 extend from bottom wall 4 to the rear side of solar panel 2. Such a rib construction with strengthening ribs 11 gives panel holder 3 an optimal stiffness and bending strength. Panel holder 3 thereby provides solar panel 2 with an additional support. A relatively thin solar panel 2 can thus be reliably applied, which results in a considerable reduction in the weight of the device. A glass solar panel with a thickness of only 2 millimetres is thus applied in this exemplary embodiment. The device can hereby also be applied on less strong surfaces, such as for instance lightweight industrial roofs.

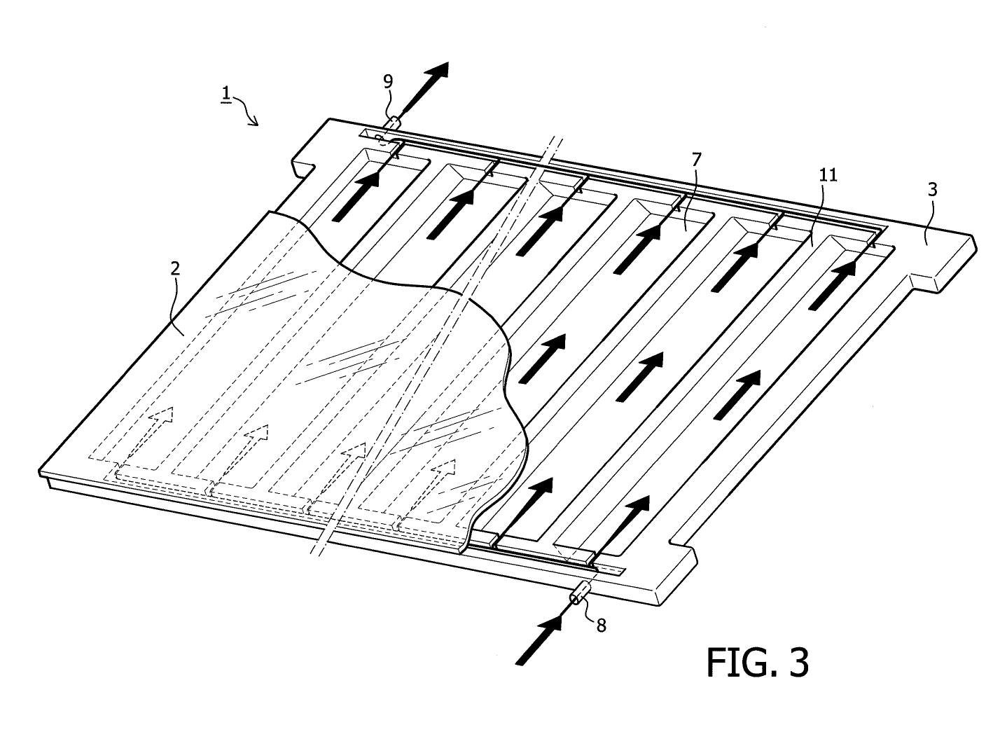

As shown in FIG. 3 in a second exemplary embodiment of a device according to the invention, device 1 comprises a solar panel 2 which is fixed onto a side wall 5 of panel holder 3 using an adhesive, in this case a glue suitable for the purpose, with airtight closure of a cavity space. Between side walls 5 strengthening ribs 11 extend from bottom wall 4 to a rear side of solar panel 2. Strengthening ribs 11 here divide the cavity space between panel holder 3 and solar panel 2 into a number of mutually separated channels 7. A heat-carrying fluid, for instance a gas such as air or a liquid such as water, can flow through channels 7 so as to enter into heat-exchanging contact with a rear side of solar panel 2 facing toward the cavity space. For this purpose an inlet 8 is provided in panel holder 3 for receiving the fluid thereat and an outlet 9 is provided in panel holder 3 for discharging the fluid therefrom. In order to cool the solar panel a cooling fluid can be provided at inlet 8, which fluid is discharged at outlet 9 in heated state after heat-exchange with solar panel 2. In order to heat the solar panel a warm fluid can be provided instead at the inlet. This may for instance be useful for the purpose of removing possible precipitation on the solar panel, such as snow or ice. Inlet 8 and outlet 9 are formed in this exemplary embodiment by a coupling piece to which respectively a feed conduit and discharge conduit can be coupled for the purpose of carrying a fluid actively through the device. The device can thus be placed for instance inside a liquid circuit so that a heat-carrying liquid is carried continuously through the device. The device can in particular also be cooled passively with air, where a convection flow through the channels occurs when the device is placed at an angle to the horizontal.

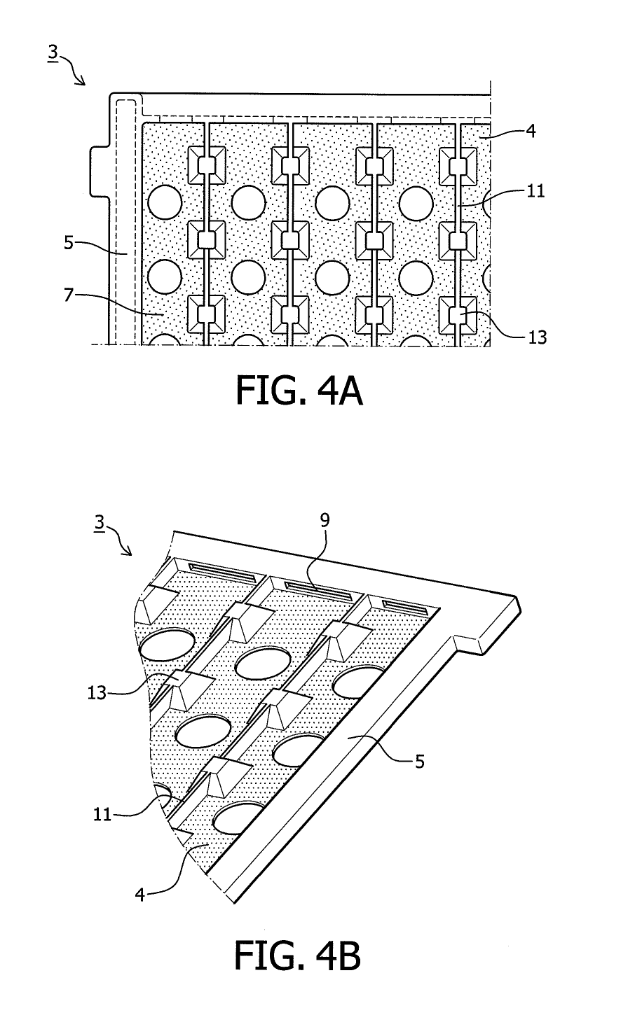

FIGS. 4A and 4B show a first exemplary embodiment of a panel holder according to the present invention. Panel holder 3 comprises an at least substantially flat bottom wall 4 from which a side wall 5 extends all around. A solar panel can be fixed onto the side wall while enclosing a cavity space 7 between bottom wall 4, side wall 5 and the solar panel. Provided inside cavity space 7 are strengthening elements 11 comprising strengthening studs 13 which support the solar panel on a rear side facing toward the cavity space. Owing to strengthening studs 13 the solar panel is supported not only by side wall 5 close to a peripheral edge thereof, but also at more central additional locations. This results in a very rigid and strong device which makes it possible to apply a thin glass panel with a thickness of 2 mm or even less, wherein the device complies with the strength requirements for such devices, as described in the IEC 61215 and IEC 61646 standards. Extending between strengthening studs 13 are strengthening ribs 11, which also increase a bending stiffness of the device. Strengthening ribs 11 moreover divide the cavity space into channels 7, which enhance a thermal regulation of the solar panel. For discharge of a medium heated in the cavity space each channel 7 is provided with an outlet opening 9 in side wall 5. Additional openings can be provided in bottom wall 4 for extra cooling. In this exemplary embodiment round openings are provided for this purpose in bottom wall 4.

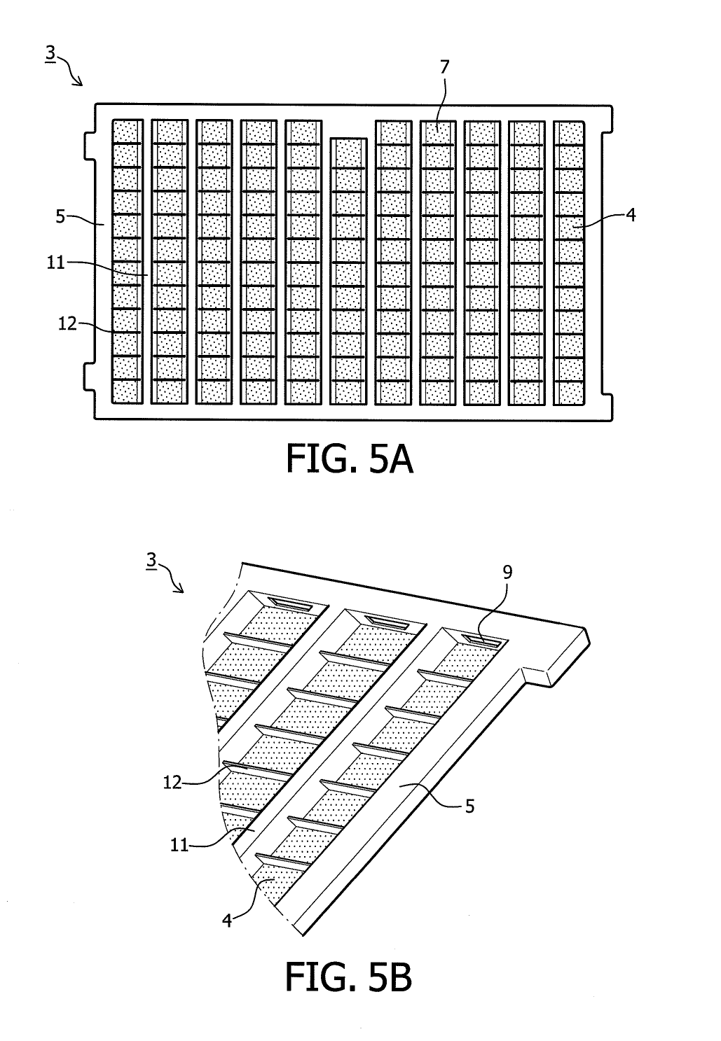

FIGS. 5A and 5B show a second exemplary embodiment of a panel holder according to the present invention. The panel holder shown herein is substantially the same as the panel holder shown in FIGS. 4A and 4B, but differs in that further strengthening ribs 12 are provided in the cavity space between the strengthening ribs 11 extending in a longitudinal direction, these ribs 12 extending in a width direction transversely of the longitudinal direction. The panel holder hereby has an optimal bending stiffness and strength in both the longitudinal direction and width direction. The further strengthening ribs 12 in the width direction can extend here to an underside of the solar panel for further support of the solar panel. In this exemplary embodiment however, the further strengthening ribs 12 leave a recess between the solar panel and an upper edge thereof so that a heat-carrying fluid received in the device can flow through channels 7 to outlets 9.

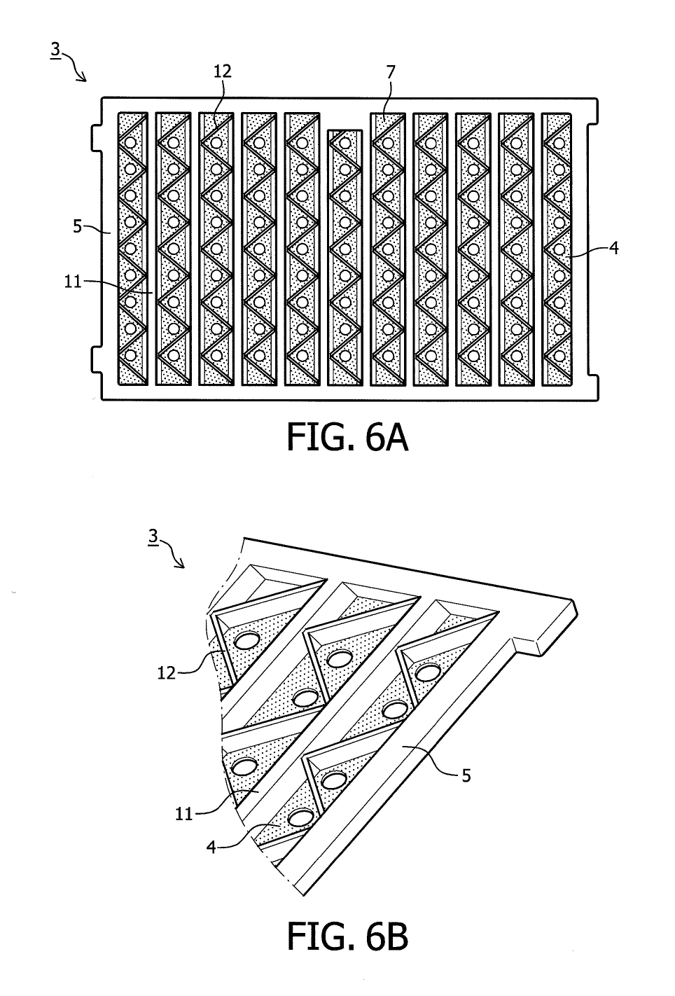

FIGS. 6A and 6B show a third exemplary embodiment of a panel holder according to the present invention. The panel holder shown herein is substantially the same as the panel holder shown in FIGS. 5A and 5B, but differs in that further strengthening ribs 12 do not lie wholly transversely of strengthening ribs 11 but extend in a diagonal direction. Such a rib construction is extremely strong and reliable and prevents a solar panel received thereon from breaking as a result of objects falling thereon, such as for instance hailstones.

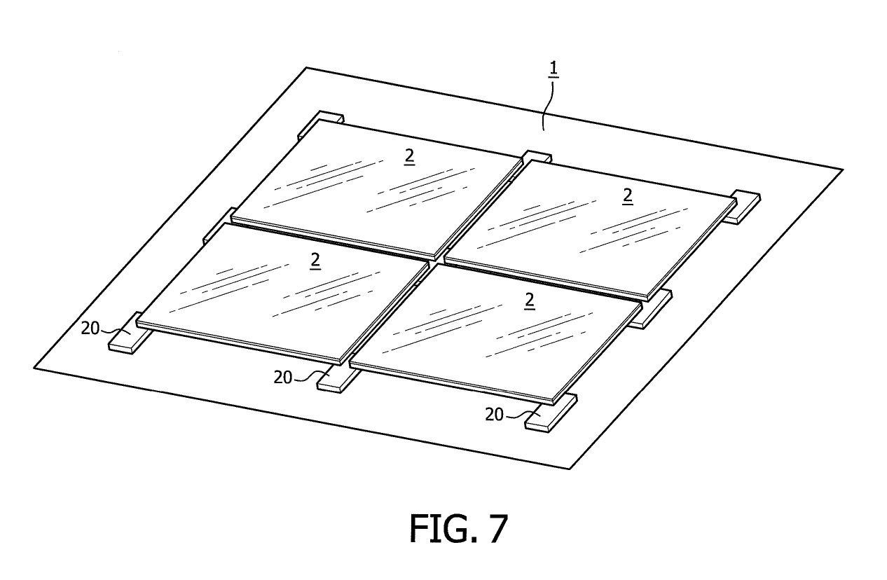

FIG. 7 is a perspective view of a first exemplary embodiment of a system for generating electrical energy from solar radiation. In this exemplary embodiment the system comprises a set of mutually coupled devices 1 according to the present invention. The coupled devices 1 comprise a panel holder 3 with solar panel 2 which is placed on support elements 20 so as to thereby support on a surface such as a roof surface. Support elements 20 are provided with fixation means for a reliable fixation to the surface. The fixation means preferably have at least substantially no adverse effect on the surface. Instead of a fastening bolt or nail penetrating the surface, use is preferably made of an adhesive as fixation means, or of a material which can be adhered to or fused with the surface. In this way a relatively heavy counterweight is moreover not required for a reliable placing on an elevated surface, such as for instance a roof surface. As further shown in FIG. 7, support elements 20 each support a plurality of panel holders. The total number of support elements required hereby remains limited. The successive solar panels 2 of the set of mutually coupled devices form an at least substantially fully closed photovoltaic surface so that an available surface area of the surface is utilized as optimally as possible for producing electrical energy.

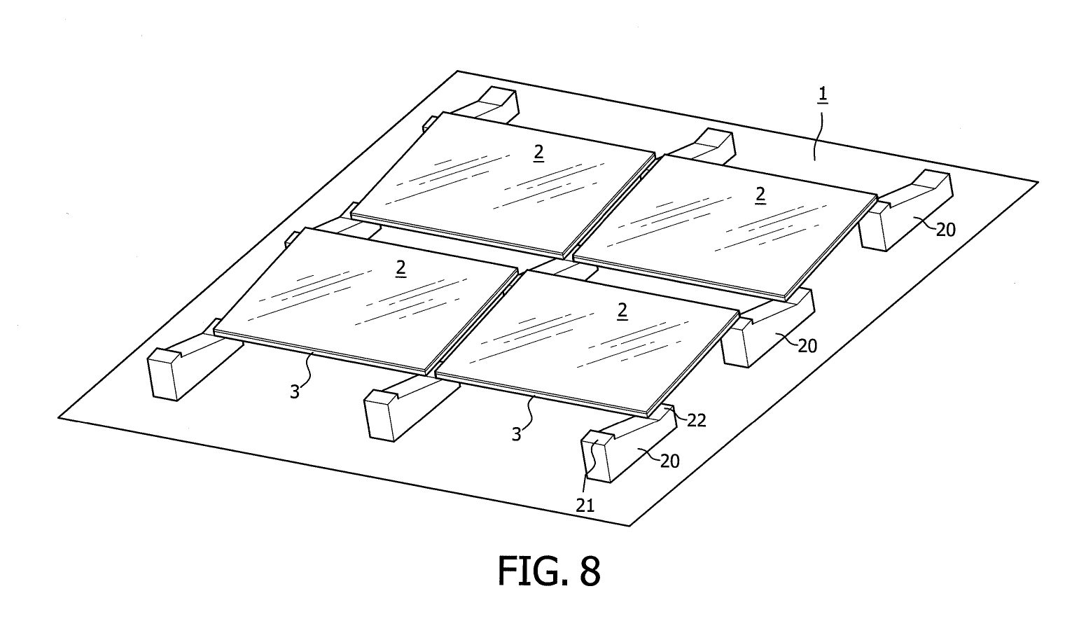

FIG. 8 is a perspective view of a second exemplary embodiment of a system for generating electrical energy from solar radiation. The system shown herein is substantially the same as the system shown in FIG. 7, but differs in that support elements 20 comprise a first support surface 22 and second support surface 21, wherein first support surface 22 of support element 20 is situated at a lower position than second support surface 21 relative to the surface. A panel holder 3 placed with a first side on first support surface 22 of a first support element 20 thus extends upward to the higher second support surface 21 of a second support element. An angle relative to the horizontal is hereby imparted to solar panels 2, which results in an efficient capture of solar radiation for the purpose of generating electrical energy therefrom.

Although the invention has been further elucidated on the basis of only several exemplary embodiments, it will be apparent that the invention is by no means limited thereto. On the contrary, many variations and embodiments are still possible within the scope of the invention for a person with ordinary skill in the art.

1. A device for generating electrical energy from solar radiation, comprising:
a panel holder with a bottom wall and a solar panel which supports on a side wall of the panel holder extending from the bottom wall,
wherein between the bottom wall and the solar panel is a cavity space in which at least one strengthening element extends from the bottom wall to a rear side of the solar panel in order to support the solar panel which comprises a glass panel with a thickness of a maximum of 4 millimetres, in particular a thickness of 2 millimetres or less.

2. The device according to claim 1, wherein the at least one strengthening element comprises a strengthening rib.

3. The device according to claim 2, wherein the at least one strengthening rib divides the cavity space between the bottom wall and the solar panel into a first channel and at least one further channel at least substantially separated therefrom, and that each channel comprises an inlet and an outlet.

4. The device according to claim 2, wherein the panel holder comprises a set of strengthening ribs which extend from the bottom wall to the solar panel and around which a channel meanders between an inlet and an outlet.

5. The device according to claim 2, wherein inside the cavity space the panel holder comprises at least a primary strengthening rib in a longitudinal direction and comprises at least a secondary strengthening rib in a transverse direction.

6. The device according to claim 5, wherein the secondary strengthening rib is connected at a first outer end to a first primary strengthening rib and is connected at an opposite, second outer end to the side wall or a subsequent further primary strengthening rib.

7. The device according to claim 6, wherein the secondary strengthening rib leaves a channel opening between the bottom wall and the solar panel.

8. The device according to claim 1, wherein the at least one strengthening element comprises a heat-conducting material.

9. The device according to claim 1, wherein the side wall is provided with a groove in which the solar panel can be guided with a peripheral edge part.

10. The device according to claim 9, wherein the peripheral edge part can be fixed clampingly in the groove.

11. The device according to claim 1, wherein the panel holder is provided with at least one support element for supporting on the surface therewith.

12. The device according to claim 11, wherein the at least one support element comprises fixation means for fixation of the panel holder to the surface.

13. The device according to claim 11, wherein the at least one support element comprises a support surface on which the panel holder supports and comprises a further support surface which is able and adapted to simultaneously receive at least one further panel holder thereon.

14. The device according to claim 13, wherein the support surface is situated at a first height relative to the surface in order to impart at least substantially the first height relative to the surface to a panel holder received thereon, and further wherein the support surface is situated at a second height, differing from the first height, relative to the surface in order to impart at least substantially the second height relative to the surface to a further panel holder received thereon.

15. The device according to claim 1, wherein the panel holder comprises a plastic, particularly a plastic chosen from the group of PP, PE, PVC, PA, PET, fibre-reinforced variants thereof, such as glass fibre variants, a combination of two or more thereof, or a thermosetting synthetic resin such as fibre-reinforced polyester as sheet moulding compound or as bulk moulding compound.

16. The device according to claim 1, wherein the panel holder and the at least one support element form an integral whole.

17. The device according to claim 1, wherein the panel holder comprises coupling means for a coupling to a further panel holder of a further device.

18. A panel holder as applied in the device as claimed in claim 1.

19. A system for generating electrical energy from solar radiation, comprising a set of mutually coupled devices as claimed in claim 1.
